(19) United States
(12) Patent Application Publication
(10) Pub. No.: US 2016/0343416 A1
(43) Pub. Date: Nov. 24, 2016

(54) Method of Dynamic Random Access Memory Resource Control

(71) Applicant: MEDIATEK INC., Hsin-Chu (TW)

(72) Inventors: Chih-Chieh Chang, Kaohsiung City (TW); Kuan-Fu Lin, Taichung City (TW); Jen-Chieh Yang, Hsinchu City (TW); Haw-Kuen Su, Taipei City (TW)

(21) Appl. No.: 15/097,294

(22) Filed: Apr. 13, 2016

Related U.S. Application Data
(60) Provisional application No. 62/164,728, filed on May 21, 2015.

(51) Int. Cl. G11C 7/10; G11C 14/00; G06F 1/32

(52) U.S. Cl. CPC G11C 7/1072; G06F 1/3275; G11C 14/0009

(57) ABSTRACT

A method of dynamic random access memory (DRAM) resource control for a DRAM manager of an electronic device is disclosed. The method comprises receiving at least one respective request message from at least one DARM user of the electronic device, each request message indicating required power information requested by the DRAM user sending the request message, and determining the DRAM to operate in one of a plurality of predetermined DRAM resource statuses respectively corresponding to a plurality of power levels according to the required power information respectively indicated by the at least one request message.

### CROSS REFERENCE TO RELATED APPLICATIONS

This application claims the benefit of U.S. Provisional Application No. 62/164,728, filed on May 21, 2015 and entitled “A Programmable DRAM Manager to Achieve Performance and Power Balance”, the contents of which are incorporated herein in their entirety.

### BACKGROUND

Mobile device (i.e. smart phone, tablet, etc.) increasingly requires DRAM size/speed for better services. However, as DRAM size/speed increase, it is critical to balance the performance and low power of the mobile device.

Conventionally, DRAM resource (i.e. DRAM frequency/voltage) is turned off only if the system of the mobile device is no required for performance and is also in lower power scenarios (for example, the mobile device is in a suspend state). On the other hand, DRAM resource is increased if the system is required for high performance in specific scenarios (for example, 4K video playback). However, the applicant notices a problem associated to DRAM resource control. More specifically, DRAM resource cannot be dynamically adjusted for performance/power balance. For example, DRAM resource cannot be turned off when APMCU or other MCU is awake. In addition, DRAM resource cannot be further adjusted when APMCU is in performance scenarios. As can be seen, there is no mechanism to well control DRAM resource.

### SUMMARY

It is therefore an objective to provide a method of DRAM resource control to solve the above problem.

One embodiment of the present invention discloses a method of dynamic random access memory (DRAM) resource control for a DRAM manager of an electronic device. The method comprises receiving at least one respective request message from at least one DARM user of the electronic device, each request message indicating required power information requested by the DRAM user sending the request message, and determining the DRAM to operate in one of a plurality of predetermined DRAM resource statuses respectively corresponding to a plurality of power levels according to the required power information respectively indicated by the at least one request message.

One embodiment of the present invention further discloses a dynamic random access memory (DRAM) manager for controlling DRAM resource of an electronic device. The DRAM manager comprises a receiving unit, for receiving at least one respective request message from at least one DARM user of the electronic device, each request message indicating required power information requested by the DRAM user sending the request message, and a determining unit, coupled to the receiving unit, for determining the DRAM to operate in one of a plurality of predetermined DRAM resource statuses respectively corresponding to a plurality of power levels according to the required power information respectively indicated by the at least one request message.

One embodiment of the present invention further discloses a dynamic random access memory (DRAM) manager for controlling DRAM resource of an electronic device. The DRAM manager comprises a non-transitory computer-readable medium for storing program code corresponding to a process, and a processor coupled to the non-transitory computer-readable medium, for processing the program code to execute the process, wherein the process comprises receiving at least one respective request message from at least one DARM user of the electronic device, each request message indicating required power information requested by the DRAM user sending the request message, and determining the DRAM to operate in one of a plurality of predetermined DRAM resource statuses respectively corresponding to a plurality of power levels according to the required power information respectively indicated by the at least one request message.

One embodiment of the present invention further discloses an electronic device. The electronic device comprises at least one DRAM user, a dynamic random access memory (DRAM) manager for DRAM resource control, coupled to the at least a DRAM user, wherein the DRAM manager is used for receiving at least one respective request message from the at least one DARM user of the electronic device, each request message indicating required power information requested by the DRAM user sending the request message, determining the DRAM to operate in one of a plurality of predetermined DRAM resource statuses respectively corresponding to a plurality of power levels according to the required power information respectively indicated by the at least one request message, and transmitting a control signaling according to the determination, and at least one controller, coupled to the DRAM manager, for receiving the control signaling from the DARM manager and therefore adjusting the DRAM resource according to the received control signaling.

One embodiment of the present invention further discloses a dynamic random access memory (DRAM) user of an electronic device. The DRAM user comprises a central processing unit for determining required power information, and a transmitting unit for transmitting a request message indicating the required power information to a DRAM manager.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an electronic device.

FIG. 2 is a schematic diagram of a DRAM resource control process.

FIG. 3 is a schematic diagram of an electronic device according to an embodiment of the present invention.

FIGS. 4-5 are power level chart according to an embodiment of the present invention.

FIG. 6 is a schematic diagram of an operation of a DRAM manger according to an embodiment of the present invention.

FIG. 7 is a schematic diagram of power saving advantage.

FIG. 8 is a schematic diagram of a structure of an electronic device according to an embodiment of the present invention.

### DETAILED DESCRIPTION

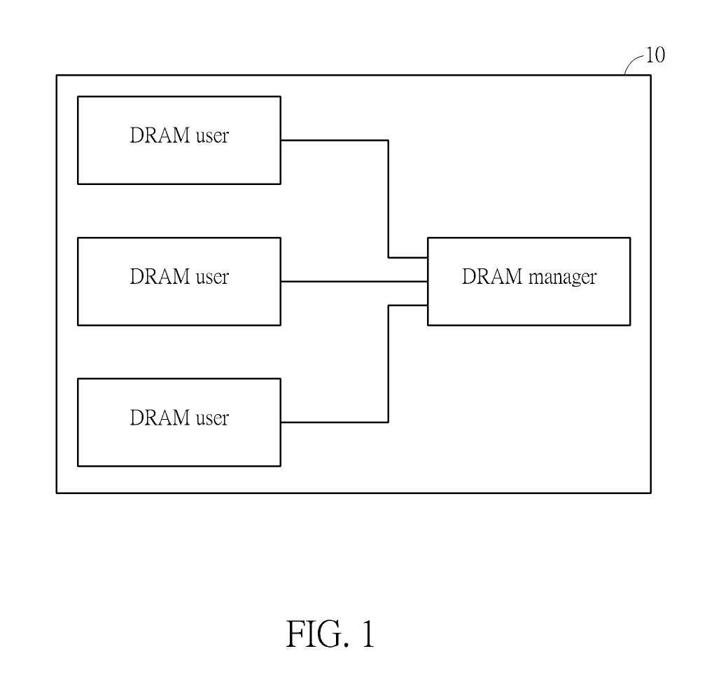

Please refer to FIG. 1, which is a schematic diagram of an electronic device 10 according to an embodiment of the present invention. For example, the electronic device 10 may be a mobile device such as a cellular telephone or smart phone or tablet. Alternatively, the electronic device may be a portable computer such as a laptop. The electronic device 10 can include a plurality of DRAM users and a DRAM manager, which can be coupled to the plurality of DRAM users for DRAM resource management of the electronic device 10. In this article, DRAM resource includes but not limited to DRAM frequency and DRAM voltage. The details are as follows.

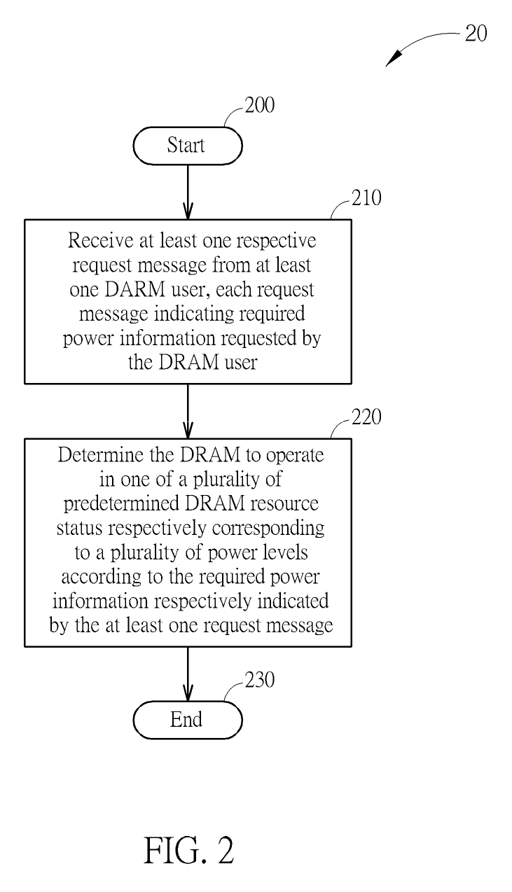

Please refer to FIG. 2, which is a schematic diagram of a DRAM resource control process 20 according to an embodiment of the present invention. The DRAM resource control process 20 may (but not limitedly) be used for the DRAM manager of FIG. 1, and includes following steps:

Step 200: Start.

Step 210: Receive at least one respective request message from at least one DARM user, each request message indicating required power information requested by the DRAM user.

Step 220: Determine the DRAM to operate in one of a plurality of predetermined DRAM resource statuses respectively corresponding to a plurality of power levels according to the required power information respectively indicated by the at least one request message.

Step 230: End.

According to the DRAM resource control process 20, the DRAM manager determines a proper DRAM resource statuses for the DRAM of the electronic device 10 to operate in a corresponding power level according to the required power information indicated in the request messages received from the DRAM users. The request messages can have different types or priorities. In one embodiment, the request message can have two types/priorities: a first priority, which indicates that DRAM can be turned off to a specific power level; and a second priority, which indicates that the DRAM should be changed to a specific power level. With such a manner, DRAM resource of the electronic device 10 can be adjusted based on performance/power requirements of the DRAM users. For example, the DRAM resource may be turned off if no performance is needed or turned off to a power level. Or, the DRAM resource may be turned on to a suitable power level if performance is needed.

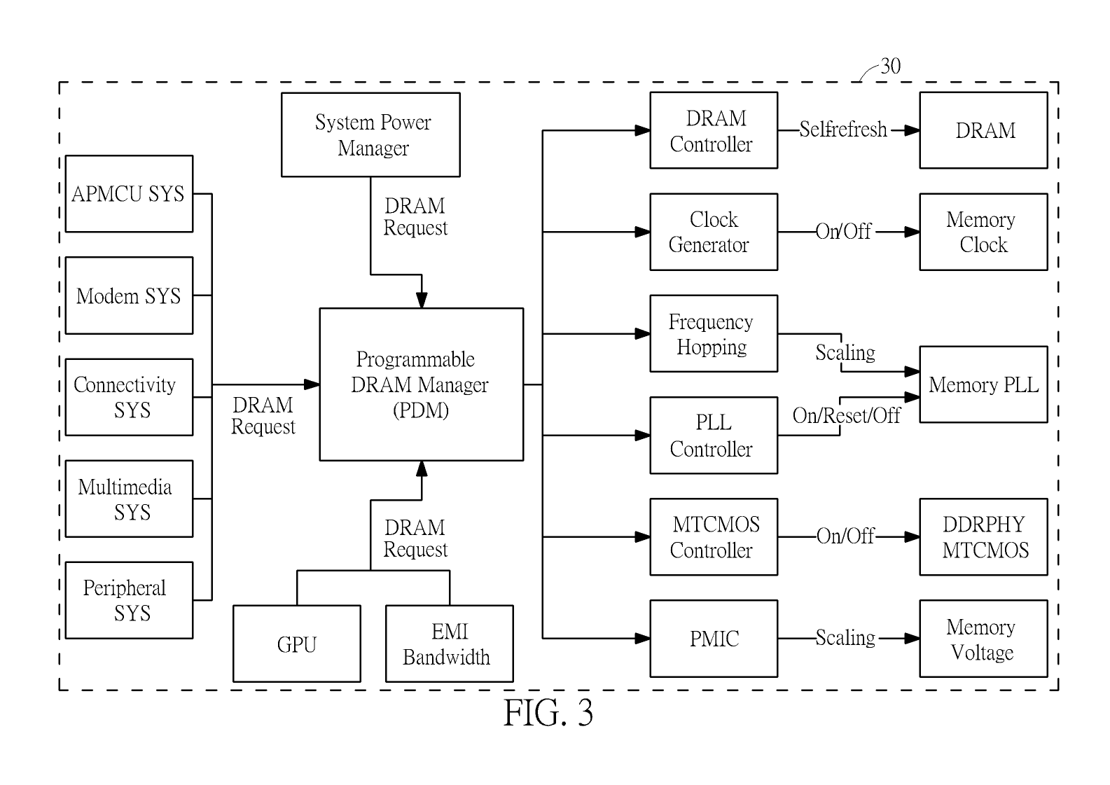

Please refer to FIG. 3, which is a schematic diagram of an electronic device 30 according to an embodiment of the present invention. The electronic device 30 includes three kinds of elements, DRAM user, DRAM manager and controller. One or more DRAM user can be implemented, for example, including one or more of following users: application microcontroller unit (APMCU) system, modem system, connectivity system, multimedia system, peripheral system, system power manager, graphics processing unit (GPU) and EMI bandwidth. The DRAM manager includes programmable DRAM manger (PDM). One or more controllers can be implemented, for example, including DARM controller, clock generator, frequency hopping, PLL controller, MTCMOS controller and power management integrated circuits (PMIC) for respectively controlling DRAM, memory clock, memory PLL, DDR DRAM physical interface Multi-threshold Complementary Metal-Oxide-Semiconductor (DDRPHY MTCMOS) and memory voltage. In other words, DRAM resources controlled by the PDM can include one or more of following resources DRAM, memory clock, memory PLL, DDRPHY MTCMOS and memory voltage of the electronic device 30. In practical, based on the DRAM resource control process 20 but not limited thereto, DRAM users (i.e. one or more of APMCU system, modem system, connectivity system, multimedia system, peripheral system, system power manager, GPU and EMI bandwidth) may transmit respective DRAM requests to the PDM. The PDM takes all or at least part of the DRAM requests for consideration and then determines the DRAM of the electronic device 30 to operate in a predetermined DRAM resource status selected from a plurality of predetermined DRAM resource statuses.

In one example, the APMCU can send DRAM requests to the PDM according to CPU cache miss rate or an idle signal for example. To be more specific, when the miss rate is lower, the DRAM can be turned to a lower power level with lower power consumption. Additionally or alternatively, when the miss rate is higher, the DRAM can be turned to a higher power level with a faster ready time.

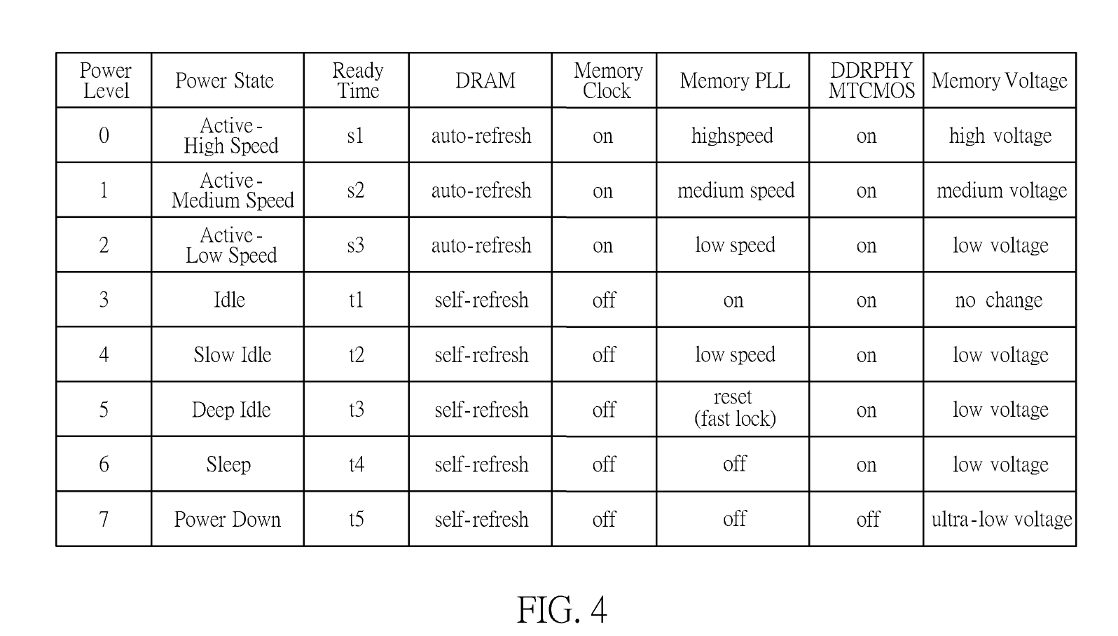

Please refer to FIG. 4, which is a power level chart according to an embodiment of the present invention. As can be seen, power levels can be associated with a plurality of power states of the DRAM. Alternatively or additionally, the power levels can be associated with a plurality sets of one or more operating parameters of the DRAM. In other words, there can be a plurality of DRAM resource statuses, respectively representing corresponding power levels, power states, and/or sets of one or more operating parameters. The operating parameters, for example, can include one or more of ready time, DRAM refresh, memory clock, memory PLL, DDRPHY MTCMOS and memory voltage. As shown in FIG. 4, power levels P0-P2 represents active states with three different speeds (i.e. high speed, medium speed and low speed). Power levels P3-P7 represents idle states with different speeds (i.e. idle, slow idle, deep idle), sleep and power down. In an embodiment, required power information indicated by a request message represents one of power levels P0-P7. Thus, when the PDM receives one or more request messages from one or more DRAM users (i.e. any of APMCU system, modem system, connectivity system, multimedia system, peripheral system, system power manager, GPU and EMI bandwidth), the PDM knows either or both of the performance requirement and power requirement of the DRAM user(s), so at to determine a proper DRAM resource status for the DRAM user(s).

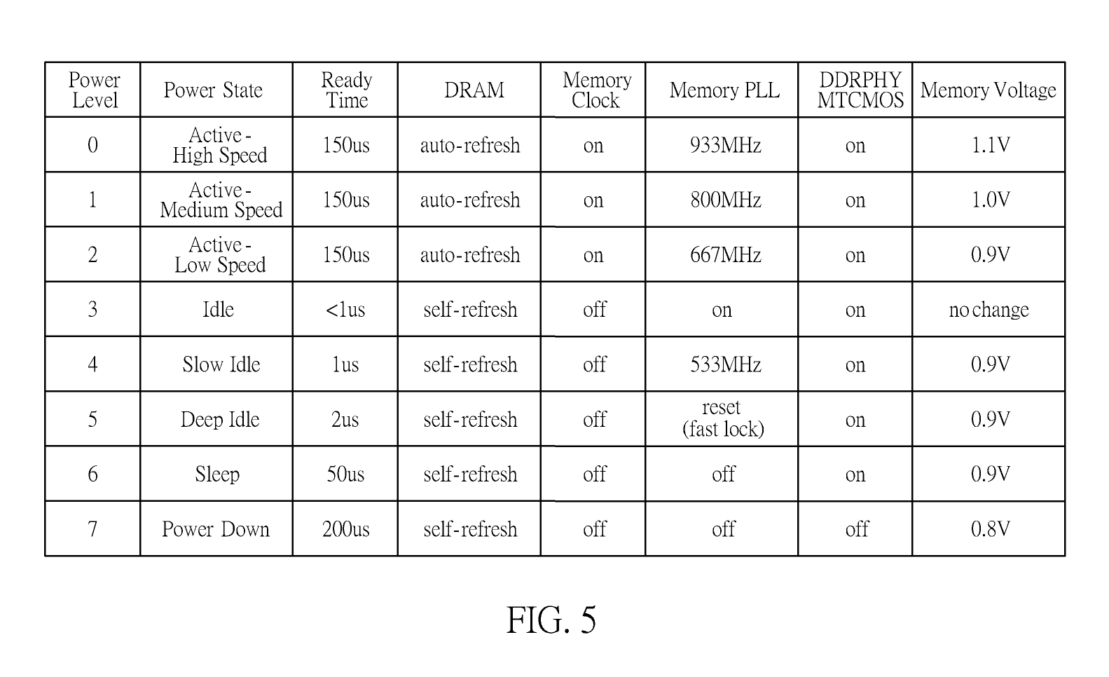

In addition, please also refer to FIG. 5 for an example regarding DRAM operating parameters. As shown in FIG. 5, power levels P0-P2 represents ready time in 150 us, DRAM with “auto-refresh”, memory clock with “on” state, memory PLL from high to lower speed, such as 933 MHz, 800 MHz and 667 MHz, DDRPHY MTCMOS with “on” state, and memory voltage from high to low voltage, such as 1.1V, 1V and 09V. Power levels P3-P6 represents DRAM with “self-refresh” state, memory clock with “off” state, DDRPHY MTCMOS with “on” state. In addition, power level P7 represents ready time in 200 us, DRAM with “self-refresh” state, memory clock, memory PLL and DDRPHY MTCMOS with “off” state, and memory voltage in lowest state, such as 0.8V. Note that, FIG. 5 is simply utilized for illustrating DRAM resource statuses. Numbers or values of the DRAM operating parameters are also illustrated for exemplification and not for limiting purpose.

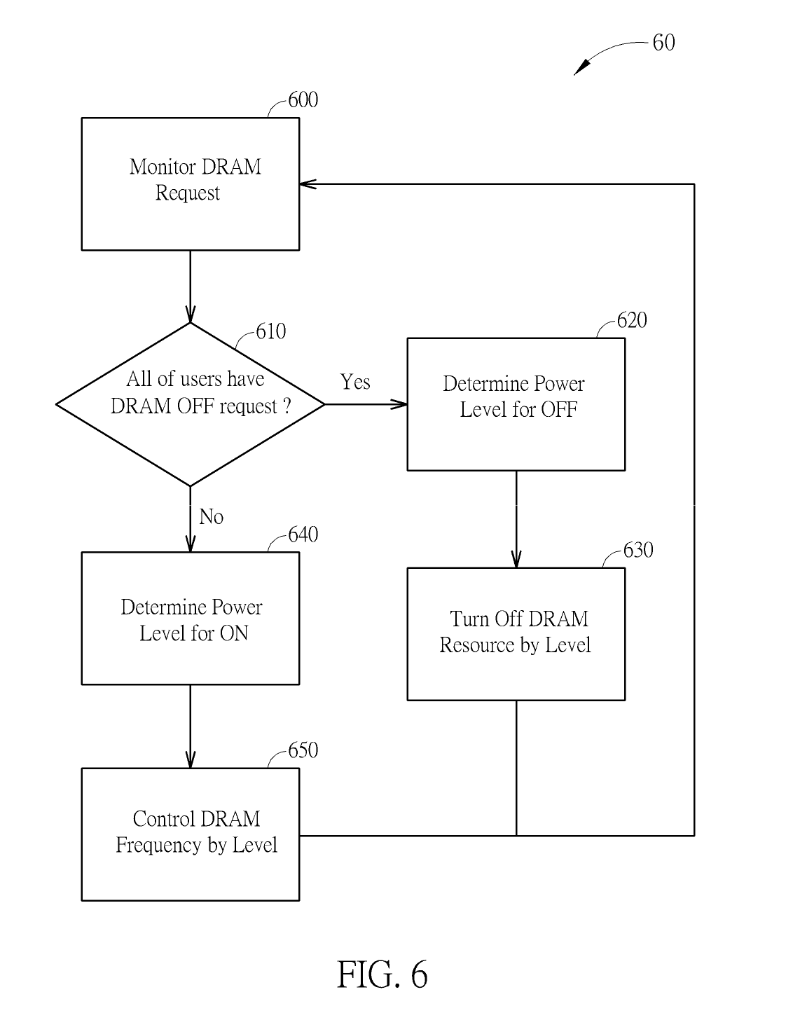

Please refer to FIG. 6, which illustrates an operation of a PDM can be summarized as a process 60 for DRAM resource control. The PDM can be the PDM in FIG. 3 but not limited thereto. As shown in FIG. 6, the process 60 includes following steps:

Step 600: Monitor DRAM request.

Step 610: All of DRAM users have DRAM off request. If yes, goes to step 620; If No, goes to step 640.

Step 620: Determine power level for OFF.

Step 630: Turn off DRAM resource by power level, and then goes back to step 600.

Step 640: Determine power level for ON.

Step 650: Control DRAM frequency by power level, and then goes back to step 600.

Note that, DRAM request sent from the DRAM user includes two types. “DRAM OFF” request means DARM can be off to a specific power level. On the other hand, “DARM ON” request can mean that DRAM frequency should be changed to a specific power level. Based on the process 60, after the PDM receives “DRAM OFF” request, the PDM determines a suitable power level for the DRAM to operate in. For example, the PDM determines one power level from the power levels P3-P7 for the DRAM, and turns off the DRAM resource (i.e. ready time, DRAM refresh, memory clock, memory PLL, DDRPHY MTCMOS and memory voltage) according to the determined power level shown in FIG. 5. On the other hand, if the requests are not all off, the PDM determines one power level from the power level P0-P2 for the DRAM, and adjusts the DRAM resource according to the determined power level shown in FIG. 5.

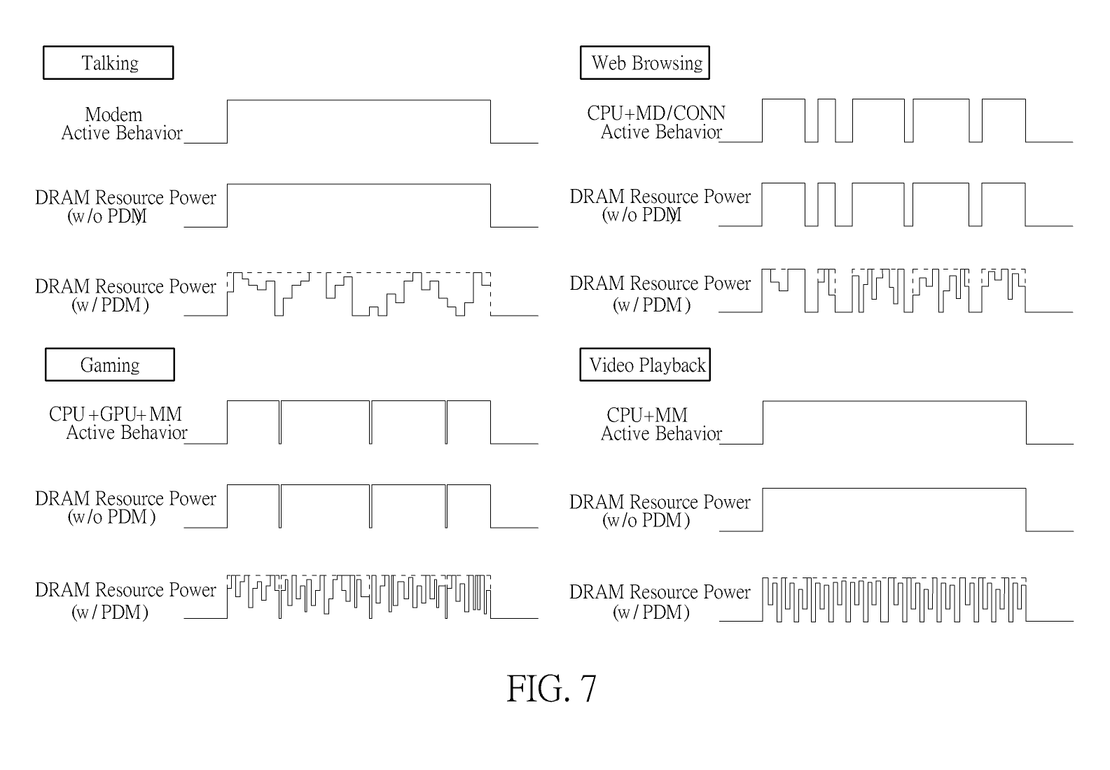

With the PDM of the present invention, DRAM resource can be dynamically adjusted to be operate at a proper power level of a plurality of power levels, so as to save power of the electronic device 30 and maintain either or both of performance requirement and power requirement of the electronic device 30. In detail, please refer to FIG. 7, which illustrates power saving advantage. FIG. 7 may be explained by referring to electronic device 30 but not limited thereto. The electronic device 30 may be a mobile device and has different operating modes, such as talking mode, gaming mode, web browsing mode and video playback mode. As can be seen, without the PDM, DRAM resource power cannot be finely adjusted in each operating mode. On the other hand, with the PDM, DRAM resource power can be finely adjusted (i.e. based on the power level chart shown in FIG. 5), to balance the performance and low power of the mobile device.

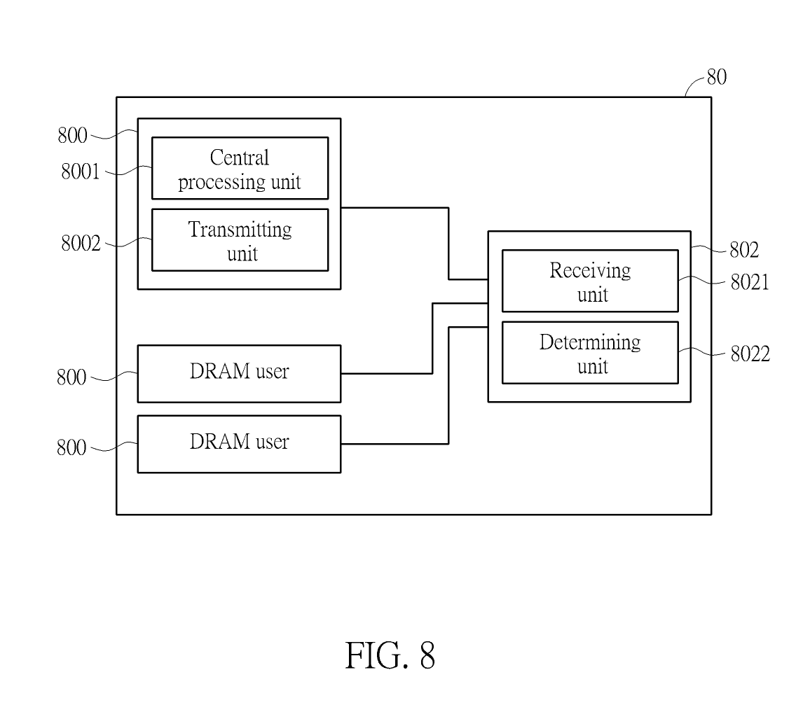

Those skilled in the art may realize the DRAM resource control process 20 by means of software, hardware or their combinations. For example, the DRAM manager (i.e. PDM) includes a processor and a memory, which may be any data storage devices, such as a read-only memory (ROM), for storing a program code compiled from the DRAM resource control process 20, thereafter read and processed by the processor to execute and realize steps of the DRAM resource control process 20. Or, please refer to FIG. 8, which illustrates a structure of a DRAM user 800 and a DRAM manager 802 of an electronic device 80. In detail, the DRAM manager 802 includes a receiving unit 8021 for receiving at least one respective request message from the DARM user 800, wherein the request message indicates required power information requested by the DRAM user 800, and a determining unit 8022, which is coupled to the receiving unit 8021, for determining the DRAM to operate in a determined power level according to the required power information indicated in the request message sent from the DRAM user 800. On the other hand, the DRAM user 800 includes a central processing unit 8001 for determining required power information for operation or performance, and a transmitting unit 8002 for transmitting a request message indicating the required power information to the DRAM manager 802. In an example, the central processing unit 8001 may determine the required power information according to a cache miss rate. In another example, the central processing unit 8001 may determine the required power information according to an idle signal.

In conclusion, the embodiments address to dynamical DRAM resource control. In other words, the DRAM manager can dynamically adjust DRAM resource of an electronic device to a proper DRAM resource status according to either or both of performance and power requirements of DRAM users, so as to save power but still maintain the performance of the electronic device.

In detail, DRAM resources can be administrated by a module, for example, PDM in the embodiments. According to different degrees of power to be saved, the DRAM can have different power levels, and/or different combinations of operational parameters. In addition, each DRAM user can dynamically send respective requests to the PDM. After PDM considers the request(s), it can control the DRAM to be at an appropriate power level or power state. In addition, the DRAM resource status can more reflect requirements of DRAM users to achieve balance between performance and power. For example, the DRAM can be turned off if it is not used by any users. Additionally or alternatively, it can be turned on in an appropriate gear. In one example case, even when an APMCU or other MCU is awake, the DRAM resource can be still dynamically turned on and off. In a second example case, even in performance scenarios, the DRAM resources can be dynamically adjusted to save power.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of dynamic random access memory (DRAM) resource control for a DRAM manager of an electronic device, the method comprising:
receiving at least one respective request message from at least one DARM user of the electronic device, each request message indicating required power information requested by the DRAM user sending the request message; and
determining the DRAM to operate in one of a plurality of predetermined DRAM resource statuses respectively corresponding to a plurality of power levels according to the required power information respectively indicated by the at least one request message.

2. The method of claim 1, wherein the power levels are associated with either or both of a plurality of power states of the DRAM and a plurality sets of one or more operating parameters of the DRAM.

3. The method of claim 2, wherein the one or more operating parameters of the DRAM include at least one of a ready time, a refresh mechanism, a state of memory clock, a state and speed of PLL, a state of DDR DRAM physical interface (DDRPHY) Multi-threshold Complementary Metal-Oxide-Semiconductor (MTCMOS), and a memory voltage.

4. The method of claim 2, wherein the power states include at least two of active, idle, sleep, and power down.

5. The method of claim 2, wherein the power states include at least two of a plurality of different active states associated with different speeds, a plurality of idle states associated with different speeds, sleep, and power down.

6. The method of claim 1, wherein the required power information indicated by each of the at least one received request message represented one of the power levels.

7. The method of claim 6, wherein the determining step comprises:
determining the DRAM to operate in one of the predetermined DRAM resource statuses corresponding to a lowest power level of the power levels when none of the at least one DRAM user sends any request message or all of the at least one received request message represents the lowest power level.

8. The method of claim 6, wherein the determining step comprises:
determining the DRAM to operate in one of the predetermined DRAM resource statuses corresponding to one of the power levels except the lowest power level when at least one received request message indicates a power level higher than the lowest power level.

9. The method of claim 6, wherein the determining step comprises:
determining the DRAM to operate in one of the predetermined DRAM resource statuses corresponding to the highest level of the at least one level respectively indicated by the at least one received request message.

10. A dynamic random access memory (DRAM) manager for controlling DRAM resource of an electronic device comprising:
a receiving unit, for receiving at least one respective request message from at least one DARM user of the electronic device, each request message indicating required power information requested by the DRAM user sending the request message; and
a determining unit, coupled to the receiving unit, for determining the DRAM to operate in one of a plurality of predetermined DRAM resource statuses respectively corresponding to a plurality of power levels according to the required power information respectively indicated by the at least one request message.

11. The method of claim 10, wherein the power levels are associated with either or both of a plurality of power states of the DRAM and a plurality sets of one or more operating parameters of the DRAM.

12. The method of claim 11, wherein the one or more operating parameters of the DRAM include at least one of a ready time, a refresh mechanism, a state of memory clock, a state and speed of PLL, a state of DDR DRAM physical interface (DDRPHY) Multi-threshold Complementary Metal-Oxide-Semiconductor (MTCMOS), and a memory voltage.

13. The method of claim 11, wherein the power states include at least two of active, idle, sleep, and power down.

14. The method of claim 11, wherein the power states include at least two of a plurality of different active states associated with different speeds, a plurality of idle states associated with different speeds, sleep, and power down.

15. The method of claim 10, wherein the required power information indicated by each of the at least one received request message represented one of the power levels.

16. The method of claim 15, wherein the determining unit further used for determining the DRAM to operate in one of the predetermined DRAM resource statuses corresponding to a lowest power level of the power levels when none of the at least one DRAM user sends any request message or all of the at least one received request message represents the lowest power level.

17. The method of claim 15, wherein the determining unit further used for determining the DRAM to operate in one of the predetermined DRAM resource statuses corresponding to one of the power levels except the lowest power level when at least one received request message indicates a power level higher than the lowest power level.

18. The method of claim 15, wherein the determining unit further used for determining the DRAM to operate in one of the predetermined DRAM resource statuses corresponding to the highest level of the at least one level respectively indicated by the at least one received request message.

19. A dynamic random access memory (DRAM) manager for controlling DRAM resource of an electronic device comprising:
a non-transitory computer-readable medium for storing program code corresponding to a process; and
a processor coupled to the non-transitory computer-readable medium, for processing the program code to execute the process, wherein the process comprises:
receiving at least one respective request message from at least one DARM user of the electronic device, each request message indicating required power information requested by the DRAM user sending the request message; and
determining the DRAM to operate in one of a plurality of predetermined DRAM resource statuses respectively corresponding to a plurality of power levels according to the required power information respectively indicated by the at least one request message.

20. The method of claim 19, wherein the power levels are associated with either or both of a plurality of power states of the DRAM and a plurality sets of one or more operating parameters of the DRAM.

21. The method of claim 20, wherein the one or more operating parameters of the DRAM include at least one of a ready time, a refresh mechanism, a state of memory clock, a state and speed of PLL, a state of DDR DRAM physical interface (DDRPHY) Multi-threshold Complementary Metal-Oxide-Semiconductor (MTCMOS), and a memory voltage.

22. The method of claim 20, wherein the power states include at least two of active, idle, sleep, and power down.

23. The method of claim 20, wherein the power states include at least two of a plurality of different active states associated with different speeds, a plurality of idle states associated with different speeds, sleep, and power down.

24. The method of claim 19, wherein the required power information indicated by each of the at least one received request message represented one of the power levels.

25. The method of claim 24, wherein the process further comprises:
determining the DRAM to operate in one of the predetermined DRAM resource statuses corresponding to a lowest power level of the power levels when none of the at least one DRAM user sends any request message or all of the at least one received request message represents the lowest power level.

26. The method of claim 24, wherein the process further comprises:
determining the DRAM to operate in one of the predetermined DRAM resource statuses corresponding to one of the power levels except the lowest power level when at least one received request message indicates a power level higher than the lowest power level.

27. The method of claim 24, wherein the process further comprises:
determining the DRAM to operate in one of the predetermined DRAM resource statuses corresponding to the highest level of the at least one level respectively indicated by the at least one received request message.

28. An electronic device comprising:
at least one DRAM user;
a dynamic random access memory (DRAM) manager for DRAM resource control, coupled to the at least a DRAM user, wherein the DRAM manager is used for receiving at least one respective request message from the at least one DARM user of the electronic device, each request message indicating required power information requested by the DRAM user sending the request message, determining the DRAM to operate in one of a plurality of predetermined DRAM resource statuses respectively corresponding to a plurality of power levels according to the required power information respectively indicated by the at least one request message, and transmitting a control signaling according to the determination; and
at least one controller, coupled to the DRAM manager, for receiving the control signaling from the DARM manager and therefore adjusting the DRAM resource according to the received control signaling.

29. The method of claim 28, wherein the power levels are associated with either or both of a plurality of power states of the DRAM and a plurality sets of one or more operating parameters of the DRAM.

30. The method of claim 29, wherein the one or more operating parameters of the DRAM include at least one of a ready time, a refresh mechanism, a state of memory clock, a state and speed of PLL, a state of DDR DRAM physical interface (DDRPHY) Multi-threshold Complementary Metal-Oxide-Semiconductor (MTCMOS), and a memory voltage.

31. The method of claim 29, wherein the power states include at least two of active, idle, sleep, and power down.

32. The method of claim 29, wherein the power states include at least two of a plurality of different active states associated with different speeds, a plurality of idle states associated with different speeds, sleep, and power down.

33. The method of claim 28, wherein the required power information indicated by each of the at least one received request message represented one of the power levels.

34. The method of claim 33, wherein the DRAM manager further used for determining the DRAM to operate in one of the predetermined DRAM resource statuses corresponding to a lowest power level of the power levels when none of the at least one DRAM user sends any request message or all of the at least one received request message represents the lowest power level.

35. The method of claim 33, wherein the DRAM manager further used for
determining the DRAM to operate in one of the predetermined DRAM resource statuses corresponding to one of the power levels except the lowest power level when at least one received request message indicates a power level higher than the lowest power level.

36. The method of claim 33, wherein the DRAM manager further used for determining the DRAM to operate in one of the predetermined DRAM resource statuses corresponding to the highest level of the at least one level respectively indicated by the at least one received request message.

37. A dynamic random access memory (DRAM) user comprising:
a central processing unit for determining required power information ; and
a transmitting unit for transmitting a request message indicating the required power information to a DRAM manager.

38. The method of claim 37, wherein the required power information indicated by the request message represented one of a plurality of power levels.

39. The method of claim 38, wherein the power levels are associated with either or both of a plurality of power states of the DRAM and a plurality sets of one or more operating parameters of the DARM.
